(19) United States
(12) Patent Application Publication
(10) Pub. No.: US 2026/0074140 A1
(43) Pub. Date: Mar. 12, 2026

(54) MULTI-BEAM CHARGED PARTICLE MICROSCOPE FOR INSPECTION WITH INCREASED THROUGHPUT

(71) Applicant: Carl Zeiss MultiSEM GmbH, Oberkochen (DE)

(72) Inventors: Kai SCHUBERT, Oberkochen (DE); Sandra VOGEL, Oberkochen (DE); Dirk ZEIDLER, Oberkochen (DE)

(21) Appl. No.: 19/388,655

(22) Filed: Nov. 13, 2025

Related U.S. Application Data
(63) Continuation of application No. PCT/EP2024/025162, filed on May 13, 2024.

(30) Foreign Application Priority Data
May 22, 2023 (DE) 10 2023 204 715.2

(51) Int. Cl. H01J 37/153; H01J 37/22; H01J 37/28

(52) U.S. Cl. CPC H01J 37/153; H01J 37/222; H01J 37/28; H01J 2237/2817; H01J 2237/2826

(57) ABSTRACT

A multi-beam charged particle system is configured to execute a series of image acquisitions at a series of inspection sites and for determining an adjustment of an image acquisition at a subsequent inspection from previous image acquisitions at previous inspection sites. The disclosure can be applied, for example, to multi-beam charged particle beam system for high-throughput wafer inspection tasks. A method of operating a multi-beam charged particle system is provided. The system and method can exhibit improved throughput.

### CROSS-REFERENCE TO RELATED APPLICATIONS

The present application is a continuation of, and claims benefit under 35 USC 120 to, international application No. PCT/EP2024/025162, filed May 13, 2024, which claims benefit under 35 USC 119 of German Application No. 10 2023 204 715.2, filed May 22, 2023. The entire disclosure of each of these applications is incorporated by reference herein.

### FIELD

The disclosure relates to a multi-beam charged particle microscope, and a related system and method. The disclosure can be implemented to inspect semiconductor features. The microscope and method can exhibit improved throughput.

### BACKGROUND

WO 2005/024881 A2 discloses an electron microscope system which operates with a multiplicity of electron beamlets for the parallel scanning of an object to be inspected with a bundle of electron beamlets. The bundle of primary charged particle beamlets is generated by directing a primary charged particle beam onto a multi-beam forming unit, comprising at least one multi-aperture plate, which has a multiplicity of aperture openings. One portion of the electrons of the electron beam is incident onto the multi-aperture plate and is absorbed there, and another portion of the beam transmits the aperture openings of the multi-aperture plate and thereby in the beam path downstream of each aperture opening an electron beamlet is formed whose cross section is defined by the cross section of the respective aperture opening. The plurality of primary charged particle beamlets are focused by an objective lens on a surface of a sample and trigger secondary electrons or backscattered electrons to emanate as secondary electron beamlets from the sample, which are collected and imaged onto a detector. The secondary beamlets are incident onto a separate detector element or group of detector elements, so that the secondary electron intensities detected therewith provide information relating to the surface of the sample at the location where the corresponding primary beamlet is incident onto the sample. The bundle of primary beamlets is scanned systematically over the surface of the sample and an electron microscopic image of the sample is generated in the usual way of scanning electron microscopes.

To achieve a relatively high-resolution image, the surface of the object to be investigated is arranged in a best focal plane of each primary beamlet. A depth of focus is typically about 700 nm or less, for example 500 nm, 300 nm or even less. The axial position of the surface of the object and the position of the image plane, in which the focus points of the plurality of beamlets is formed, is controlled with relatively high precision. Therefore, before each image acquisition, the systems typically call a routine for a proper, but time-consuming focus adjustment. For example, DE 10 2021 200 799 B3 discloses a focus adjustment method comprising image acquisition of a series of images at different focus position or z-position of a sample stage and analyzing the result to derive the best focus setting. Other examples, such as disclosed in U.S. Pat. No. 10,388,487, use information which is derived from a previous measurement by a complex and time-consuming investigation of object properties and properties of the multiplicity of particle beamlets. There is a general desire for a relatively fast focus following routine for a series of inspection images, for example of inspections at a plurality of inspection sites on a wafer.

### SUMMARY

In general, the disclosure provides, for example, a multi-beam charged particle system and a method of operating a multi-beam charged particle system for a series of image acquisitions at at least one inspection site on a wafer. The system and method can exhibit increased throughput. The disclosure provides, for example, a multi-beam charged particle system and a method of operating a multi-beam charged particle system for a series of image acquisitions at series of inspection sites on a wafer. The system and method can exhibit increased throughput. In an example, the disclosure includes generating a model-based focus distribution map from a first measurement and iteratively improving subsequent image acquisitions during a series of image acquisitions on a wafer surface.

Electron microscopy according to the disclosure comprises an irradiation of a planar surface with a plurality of primary charged particle beamlets. During use, a plurality of secondary electron beamlets is generated at the interaction volumes of the plurality of primary charged particle beamlets with a wafer. The secondary electron yield at each interaction volume, in general, depends on the current and kinetic energy of corresponding primary charged particle beamlets and the material composition within the interaction volume.

According to an example, a method of wafer inspection with a multi-beam charged particle beam system comprises determining a series of inspections sites, including at least a first and a second inspection site on a wafer surface. The method further comprises acquiring a first image at the first inspection site on a wafer surface with a first imaging setting of the plurality of primary charged particle beamlets and determining a first local image contrast map LV (x,y) of the first image. The method further comprises determining a measurement value MV.1 from the first local image contrast map LV(x,y) and determining a reference value RV.1 according to the first imaging setting from a memory. The method further comprises determining at least one deviation value DV.1 between the measurement value MV.1 and the reference value RV.1. The measurement value MV.1 comprises at least one of a first focus offset FM.1, a first field curvature radius RM.1 and a first image plane tilt vector TM.1. The reference value RV.1 comprises at least one of a reference focus offset RF.1, a reference field curvature radius RR.1 and a reference image plane tilt vector TR.1.

The method can further comprise determining at least one of an adjustment of the second or subsequent inspection site and the second or subsequent imaging setting of the plurality of primary charged particle beamlets from the at least one deviation value DV.1. The method can further comprise executing the adjustment of the second or subsequent inspection site and of the second or subsequent imaging setting. The method can further comprise acquiring a second or subsequent image at the second or subsequent inspection site on the wafer surface with the second imaging or subsequent imaging setting of the plurality of primary charged particle beamlets. The method can rely relies on prior knowledge, for example on the assumption of a planar wafer surface. Therefore, the focus information determined at a first inspection site can be used for relatively fast, subsequent image acquisitions at a series of different inspection sites, for example at different positions on the planar wafer surface. The focus information determined at a first inspection site can be considered at further inspection sites at different positions and a relatively high image contrast at further inspection sites can be achieved without determining a focus position at each different inspection site.

In an example, the method comprises computing a difference DT.1 between the first image plane tilt vector TM.1 and the reference image plane tilt vector TR.1 and determining, from the difference DT.1, a tilt angle adjustment of the wafer surface with a wafer stage at the second inspection site. A tilt adjustment can be achieved by tilt actuators of a wafer stage or a wafer chuck for holding the wafer. Thereby, an unexpected deviation of an image plane tilt can be compensated during performing a series of image acquisitions at a series of inspection sites, for example at different positions on a planar wafer.

In an example, the method comprises computing a difference DF.1 between the measured focus offset FM.1 and the reference focus offset FR. 1 and determining, from the difference DF.1, at least one of an axial movement of the wafer stage and an adjustment of a focus offset of the multi-beam charged particle beam system at the second inspection site. A focus offset adjustment can be achieved by an electrostatic lens of the multi-beam charged particle beam system, or by a z-stage capable for an axial displacement of a wafer surface. Thereby, an unexpected focus offset can be compensated before an image acquisition at a subsequent inspection site. Thereby, an unexpected focus offset can be compensated during performing a series of image acquisitions, for example at a series of inspection sites at different positions on a planar wafer.

In an example, the method comprises computing a difference DR.1 between the measured field curvature radius RM.1 and the reference field curvature radius RR.1, and determining, from the difference DR.1, an adjustment of a field curvature of the multi-beam charged particle beam system at the second inspection site. A field curvature radius adjustment can be achieved by a decelerating field above the wafer surface for adjustment of the landing energy of primary charged particles, by an excitation of a magnetic lens of a compensator for field curvature of the multi-beam charged particle beam system. Thereby, an unexpected change of a field curvature radius can be compensated before an image acquisition at a subsequent inspection site. Thereby, an unexpected change of a field curvature radius can be compensated during performing a series of image acquisitions at a series of inspection sites, for example at different positions on a planar wafer.

In an example, the method is further iteratively repeated for each of a series of image acquisitions at a series of inspection sites with a series of imaging settings. Therewithin, imaging settings for each image acquisition at each inspection site can be similar of identical, or different. A series of inspection sites can comprise at least two inspections sites at two different positions on a wafer. Generally, all inspections sites can be different, or a series of inspection sites can comprise identical inspection sites for a repeated, second image acquisition at a first inspection site after a first image acquisition at the first inspection site.

In an example, the method further comprises determining a second local image contrast map LV(x,y) of the second image, determining a second measurement value MV.2 from the second local image contrast map LV(x,y), determining a second reference value RV.2 according to the second imaging setting from a memory, determining at least one second deviation value DV.2 between the second measurement value MV.2 and the second reference value RV.2, determining from the at least one second deviation value DV.2 at least one of an adjustment of a third inspection site and an adjustment of a third imaging setting of the plurality of primary charged particle beamlets, and acquiring a third image at the third inspection site on the wafer surface with the third imaging setting of the plurality of primary charged particle beamlets. The second measurement value MV.2 can comprise at least one of a second focus offset FM.2, a second field curvature radius RM.2 and a second image plane tilt vector TM.2. The second reference value RV.2 can comprise at least one of a reference focus offset RF.2, a reference field curvature radius RR.2 and a reference image plane tilt vector RT.2. Generally, in an example, the method can comprise iterating the steps of determining a local image contrast map LV(x,y), determining an ith measurement value MV.i, determining an ith reference value RV.i, determining at least one ith deviation value DV.i, determining from the at least one ith deviation value DV.i at least one of an adjustment of an (i+1)th inspection site and an adjustment of an (i+1)th imaging setting of the plurality of primary charged particle beamlets, and acquiring a subsequent (i+1)th image at the subsequent (i+1)th inspection site.

In an example, the method comprises determining, from at least three difference vectors DT.1 to DT.3, a wafer bending radius BR of a surface of a wafer and considering the wafer bending radius BR during determining the adjustment of at least one subsequent inspection site. In an example, the method comprises determining, from at least three difference vectors DT.1 to DT.3, a wedge angle W of a wafer, and considering the wafer wedge angle W during determining the adjustment of at least one subsequent inspection site. Thereby, a wafer bending, and a wafer wedge can be systematically determined during an inspection task and considered during a subsequent series of image acquisitions on the same wafer. Thereby, a deviation of a wafer surface from an expected planar surface can be determined after at least three image acquisitions at three different inspection sites. The deviation of a wafer surface from an expected planar surface can then be considered at further inspection sites and a high image contrast is achieved without determining a focus position at each inspection site.

In an example, the method further comprises tracking a series of at least three difference values DV.1 to DV.3 and analyzing whether the series of difference values DV.1 to DV.3 converges. If the series of difference values DV.1 to DV.3 is not converging, a calibration of the multi-beam charged particle beam system can be triggered.

In an example, a method comprises determining, in a local contrast map LV(x,y), a circle of maximum image contrast, and determining a diameter DVM of the circle of maximum image contrast. The field curvature radius is typically a priori known and does only slightly change during a series of image acquisitions. From the diameter DVM and the previously determined field curvature radius, a focus offset FM can be determined. Thereby, the method can help enable the determination of a focus offset from a single image of an arbitrary object. In an example, the method comprises determining a center position of the circle of maximum image contrast and determining an image plane tilt vector TM from the center position of the circle. Thereby, the method can help enable the determination of an axial position of an image plane or a wafer tilt from a single image of an arbitrary object.

In an example, a method of acquiring a series of images at an inspection site is disclosed. The method comprises acquiring a first image at the inspection site on a wafer surface with a first imaging setting of the plurality of primary charged particle beamlets. The method further comprises determining a first local image contrast map LV (x,y) of the first image and determining a measurement value MV from the first local image contrast map LV(x,y), wherein the measurement value MV comprises at least one of a first focus offset FM, a first field curvature radius RM and a first image plane tilt vector TM. The method further comprises determining a reference value RV according to the imaging setting from a memory, wherein the reference value RV comprises at least one of a reference focus offset RF, a reference field curvature radius RR and a reference image plane tilt vector TR. The method further comprises determining at least one deviation value DV between the measurement value MV and the reference value RV and determining from the at least one deviation value DV at least one of an adjustment of the inspection site and an adjustment of the imaging setting of the plurality of primary charged particle beamlets. The method further comprises executing the adjustment of the inspection site or an adjustment of the imaging setting of the plurality of primary charged particle beamlets and acquiring a second image at the inspection site on the wafer surface with the adjusted imaging setting of the plurality of primary charged particle beamlets. The adjustment of the imaging setting can comprise at least one of an adjustment of a focus offset FM of the image surface and an adjustment of an axial position of the surface of the wafer. In an example, the method comprises image processing of the series of images, for example an averaging of the series of images and an adjustment of lateral image displacements.

In an example, a multi-beam charged particle beam system for improved throughput is provided. The multi-beam charged particle beam system comprises a control processor, including a memory for storing executable software instructions. The control processor is configured for executing the software instructions to perform any of the methods described above.

The disclosure provides a multi-beam charged particle beam system comprising an object irradiation unit with a multi-beamlet generator for generating a plurality of primary charged particle beamlets. The multi-beam charged particle beam system comprises an objective lens for focusing during use the plurality of primary charged particle beamlets into an image plane of the object irradiation unit. The multi-beam charged particle beam system comprises a first common scanning deflector for scanning the plurality or primary charged particle beamlets over an area of the image plane. The multi-beam charged particle beam system further comprises a detection unit configured for imaging a plurality of secondary electron beamlets onto an image sensor. The multi-beam charged particle beam system further comprises a beam splitter unit for guiding the plurality of primary charged particle beamlets from the multi-beamlet generator to the objective lens and for guiding the plurality of secondary electron beamlets from the objective lens to the detection unit. The detection unit comprises a second common scanning deflector for keeping the focus points of the plurality of secondary electron beamlets at a constant position of an image detector.

The multi-beam charged particle beam system can further comprise a voltage supply unit connected during use to a wafer for providing during use an extraction voltage to the wafer for generating a decelerating field for primary charged particles, corresponding to an accelerating or extraction field for the secondary electrons generated in the interaction volumes. The detection unit can comprise a plurality of adjustable electron-optical elements.

It will be understood that the disclosure is not limited to the embodiments and examples but comprises also combinations and variations of the embodiments and examples.

### BRIEF DESCRIPTION OF THE DRAWINGS

Embodiments of the present disclosure will be explained in more detail with reference to drawings, in which:

FIG. 1 is a schematic sectional view of a multi-beam charged particle system according to the first embodiment;

FIGS. 2A,2B illustrate an example of a scanning image acquisition of a surface segment of a wafer;

FIGS. 3A,3B illustrate an example of a field curvature and image plane tilt and the effect on an imaging contrast;

FIG. 3C illustrates a relation between local image contrast over defocus from an ideal focus position or beam waist;

FIGS. 4A,4B illustrate two examples of the local imaging contrast or local visibility for two different imaging settings;

FIG. 5 illustrates an example of a wafer inspection task;

FIG. 6 illustrates an example of a flow chart of a method according to the second embodiment;

FIG. 7 illustrates an example of a wafer bending;

FIG. 8 illustrates an inspection task comprising a wafer inspection at a plurality of inspection sites; and

FIGS. 9A,9B illustrates an example of a method according to the second embodiment.

### DETAILED DESCRIPTION

In the exemplary embodiments of the disclosure described below, components similar in function and structure are indicated as far as possible by similar or identical reference numerals.

Some array elements, for example the plurality of primary charged particle beamlets, are identified by a reference number. Depending on the context, the same reference number may also identify a single element of an array of elements. Each primary charged particle beamlet (3.1, 3.2, 3.3) is one of the plurality of primary charged particle beamlets (3).

The method is described with reference to semiconductor wafers as object, but the method can also be applied to mask for semiconductor wafer fabrication, which are considered in this disclosure as equivalent to semiconductor wafers.

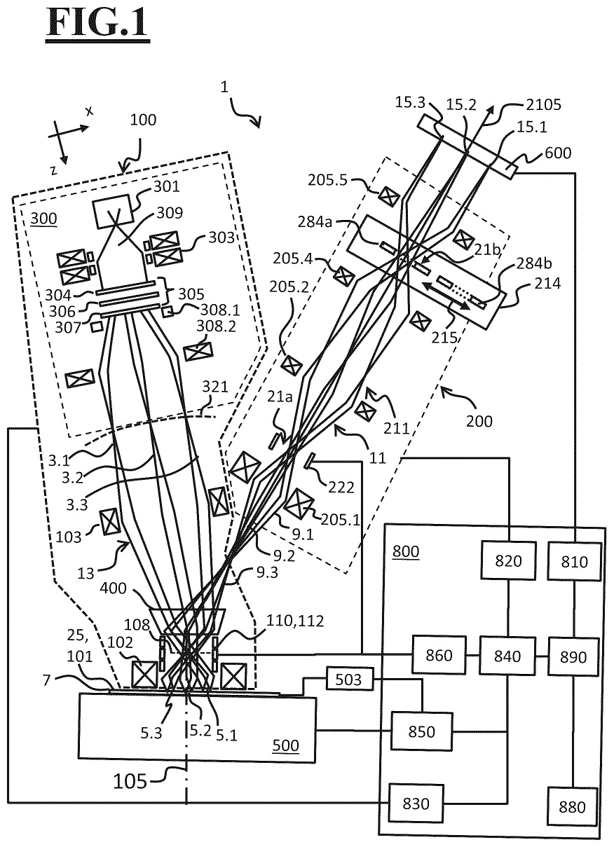

The schematic representation of FIG. 1 illustrates basic features and functions of a multi-beam charged-particle system 1 according to a first embodiment. It is to be noted that the symbols used in FIG. 1 have been chosen to symbolize their respective functionality. The type of system shown is that of a multi-beam scanning electron microscope using a plurality of primary charged particle beamlets 3 for generating a plurality of primary charged particle beam spots 5 on a surface 25 of an object 7, such as a wafer or mask substrate located with a top surface 25 in an image surface 101 of an objective lens 102. For simplicity, only three primary charged particle beamlets 3.1 to 3.3 and three primary charged particle beam spots 5.1 to 5.3 are shown. The features and functions of multi-beamlet charged-particle system 1 can be implemented using electrons or other types of primary charged particles such as ions and for example Helium ions. Further details of the microscope system 1 are provided in International Patent application PCT/EP2021/066255, filed on Jun. 16, 2021, which is hereby fully incorporated by reference.

The system 1 comprises an object irradiation unit 100 and a detection unit 200 and a secondary electron beam divider or beam splitter unit 400 for separating the secondary charged-particle beam path 11 from the primary charged-particle beam path 13. The object irradiation unit 100 comprises a charged-particle multi-beam generator 300 for generating the plurality of primary charged-particle beamlets 3 and is adapted to focus the plurality of primary charged-particle beamlets 3 into the image surface 101, in which the surface 25 of an object or wafer 7 is positioned by a sample stage 500.

The primary beam generator 300 produces a plurality of primary charged particle beamlet spots in an intermediate image surface 321. The primary beamlet generator 300 comprises at least one source 301 of primary charged particles, for example electrons. The at least one primary charged particle source 301 emits a diverging primary charged particle beam, which is collimated by at least one collimating lens 303 to form a collimated or parallel primary charged particle beam 309. The collimating lens 303 is usually consisting of one or more electrostatic or magnetic lenses, or by a combination of electrostatic and magnetic lenses. The collimated primary charged particle beam 309 is incident on the primary multi-beam forming unit 305. A multi-beam generating unit 305 is for example explained in US 2019/0259575, and in U.S. Pat. No. 10,741,355 B1, both hereby incorporated by reference. The multi-beam forming unit 305 basically comprises a first multi-aperture plate or filter plate 304 illuminated by the collimated primary charged particle beam 309. The first multi-aperture plate or filter plate 304 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least one further multi-aperture plate 306, which is located, with respect to the direction of movement of the electrons in beam 309, downstream of the first multi-aperture or filter plate 304. For example, a second multi-aperture plate 306 comprises for example four or eight of electrostatic elements for each of the plurality of apertures, for example to deflect each of the plurality of beamlets individually. The multi-beamlet forming unit 305 according to some embodiments is configured with a terminating multi-aperture plate 307. The multi-beamlet forming unit 305 is further configured with an adjacent electrostatic field lenses 308.1, which is in some examples combined in the multi-beamlet forming unit 305. Together with a second field lens 308.2, the plurality of primary charged particle beamlets 3 is focused in or in proximity of the intermediate image surface 321. The primary charged-particle source 301 and each of the active multi-aperture plates 306 are controlled by primary beam-path control module 830. The plurality of focus points of primary charged particle beamlets 3 passing the intermediate image surface 321 is imaged by field lens group 103 and objective lens 102 into the image surface 101, in which the surface 25 of the object 7 is positioned. A decelerating electrostatic field is generated between the objective lens 102 and the object surface 25 by application of a voltage to the object by the sample voltage supply 503. With the decelerating electrostatic field generated by sample voltage supply 503, a kinetic landing energy of primary electrons is adjusted to for example below 2 keV, below 1 keV, below 500 eV, below 300 eV or even less.

The object irradiation system 100 further comprises a collective multi-beam raster scanner 110 in proximity of a beam cross over 108 by which the plurality of charged particle beamlets 3 can be deflected in a direction perpendicular to the propagation direction of the charged particle beamlets 3. The propagation direction of the primary beamlets throughout the examples is in positive z-direction. Objective lens 102 and collective multi-beam raster scanner 110 are centered at an optical axis 105 of the multi-beam charged-particle system 1, which is perpendicular to wafer surface 25. The plurality of primary charged particle beamlets 3, forming the plurality of beam spots 5 arranged in a raster configuration, is scanned synchronously over the wafer surface 25. In an example, the raster configuration of the focus spots 5 of the plurality of J primary charged particle 3 is a hexagonal raster of about one hundred or more primary charged particle beamlets 3, for example J=91, J=100, or J approximately 300, for example J=331 or J=2791 or even more beamlets. The primary beam spots 5 have a distance about 6 μm to 45 μm between each other, and a diameter of below 5 nm, for example 3 nm, 2 nm or even below. In an example, the beam spot size is about 1.5 nm, and the distance between two adjacent beam spots is 8 μm. At each scan position of each of the plurality of primary beam spots 5, a plurality of secondary electrons is generated, respectively, forming the plurality of secondary electron beamlets 9 in the same raster configuration as the primary beam spots 5. The intensity of secondary charged particle beamlets 9 generated at each beam spot 5 depends on the intensity of the impinging primary charged particle beamlet 3, illuminating the corresponding spot 5, the material composition and topography of the wafer 7 under the beam spot 5, and the charging condition of the wafer 7 at the beam spot 5. The plurality of secondary charged particle beamlets 9 are accelerated by the same electrostatic field between objective lens 102 and object surface 25, generated by voltage supply 503, and are collected by objective lens 102 and pass the first collective multi-beam raster scanner 110 in opposite direction to the primary beamlets 3. The plurality of secondary beamlets 9 is scanning deflected by the first collective multi-beam raster scanner 110. The plurality of secondary charged particle beamlets 9 is then guided by secondary electron beam divider or beam splitter unit 400 to follow the secondary beam path 11 to the detection unit 200. The plurality of secondary electron beamlets 9 is travelling in opposite direction from the primary charged particle beamlets 3, and the beam splitter unit 400 is configured to separate the secondary beam path 11 from the primary beam path 13 usually via magnetic fields or a combination of magnetic and electrostatic fields.

Detection unit 200 images the secondary electron beamlets 9 onto the image sensor 600 to form there a plurality of secondary charged particle image spots 15. The detector or image sensor 600 comprises a plurality of detector pixels or individual detectors. For each of the plurality of secondary charged particle beam spots 15, the intensity is detected separately, and the property of the object surface 25 is detected with high resolution for a large image patch of the object 7 with high throughput. For example, with a raster of 10×10 beamlets with 8 μm pitch, an image patch with a diameter D of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by imaging control module 810. Details of the digital image data collection and processing, using for example parallel processing, are described in international patent application WO 2020151904 A2 and in U.S. Pat. No. 9,536,702, which are hereby incorporated by reference.

Detection unit 200 further comprises at least a second collective raster scanner 222, which is connected to scanning and imaging control unit 860. Scanning control unit 860 is configured to compensate a residual difference in position of the plurality of focus points 15 of the plurality of secondary electron beamlets 9, such that the positions of the plurality secondary electron focus spots 15 are kept constant at image sensor 600.

The detection unit 200 comprises further electrostatic or magnetic lenses 205.1 to 205.5 and a second cross over or pupil plane 21b of the plurality of secondary electron beamlets 9, in which a contrast aperture filter module 214 with a plurality of aperture filters 284a, 284b is located. The second cross over corresponds to a pupil plane 21b of the detection unit 200. In a pupil plane, a lateral coordinate with respect to the optical axis 2105 corresponds to a propagation angle of a secondary electron trajectory at the image surface 101. The propagation angle of a secondary electron trajectory is measured relative to the wafer surface normal, which is corresponding to the optical axis 2105 of the detection unit 200.

The image sensor 600 is configured by an array of sensing areas in a pattern compatible to the raster arrangement of the secondary electron beamlets 9 focused by the projecting lenses 205 onto the image sensor 600. This enables a detection of each individual secondary electron beamlet independent from the other secondary electron beamlets incident on the image sensor 600. The image sensor 600 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 600 can be configured as electron to photon conversion unit or scintillator plate arranged in the focal plane of the plurality of secondary electron particle image spots 15. In this embodiment, the image sensor 600 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is cited above and incorporated by reference.

During an acquisition of an image patch by scanning the plurality of primary charged particle beamlets 3, the stage 500 is optionally not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

During an image scan, the control unit 800 is configured to trigger the image sensor 600 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

The control unit 800 of the multi-beamlet charged-particle system 1 further comprises an-imaging control module 810, configured to receive the data streams from the image sensor 600 and to generate a digital image of the surface of the sample 7 during operation; a secondary beam-path control module 820, configured to control the lenses 205 and other components of the detection unit 200; a primary beam-path control module 830, configured to control the elements of the object irradiation unit 100, including the charged-particle multi-beamlet generator 300; a stage control module 850, configured to control the stage positioning and alignment, and including control of the sample voltage supply unit 503; a scanning operation control module 860, configured to control a scanning operation by the first collective multi-beam raster scanner 110 and the second scanning deflection system 222; a control operation processor unit 840, configured to execute inspection tasks of samples, and configured to control the modules 810, 820, 830, 850, 860, 870 and a memory 880 for storing software, instructions and image data. The control operation processor unit 840 is further connected to an interface (not shown) for exchange of data, instructions, software, or user interaction. A control unit 800 according to the first embodiment further comprises an image processing engine 890, which is configured to perform image processing operations of at least one digital image.

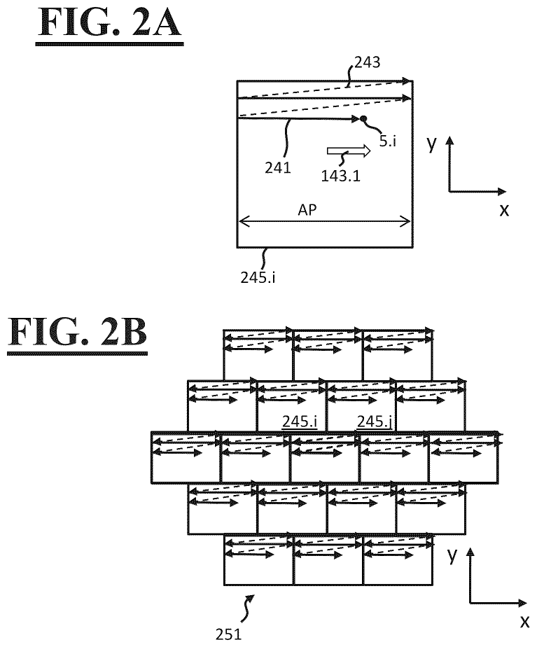

FIGS. 2A and 2B illustrate a scanning operation of the plurality of primary charged particle beamlets 3 during an image acquisition. The scanning operation control module 860 is configured to provide during use a scanning signal to scanning deflector 110. Thereby, each primary charged particle beamlet 3 is deflected by the collective multi-beam raster scanner 110 such that the corresponding focus spot 5.i is scanned over an image patch 245.i of a single beamlet (FIG. 2A). Each image patch 245.i has a diameter AP of for example 8 μm to 10 μm. The scanning operation comprises a scanning of a plurality of parallel image scanning lines 241 along scanning direction 143.1 for image acquisition. At the end of each image scanning line 241, each beamlet 3 is moved to the starting position of a next scanning line, which is also called “flyback” 243. During image acquisition along image scanning lines 241, the scanning operation is controlled to achieve a dwell time of about 50 ns at each image point, with for example 8000 images points per image scanning line 241. The time for flyback 243 can be much shorter, for example 20 ns in total. FIG. 2B shows the parallel operation of a plurality of primary charged particle beamlets 3 to acquire an image 251.1 of a surface segment 251.1 of a wafer surface, consisting of a plurality of smaller image patches 245.

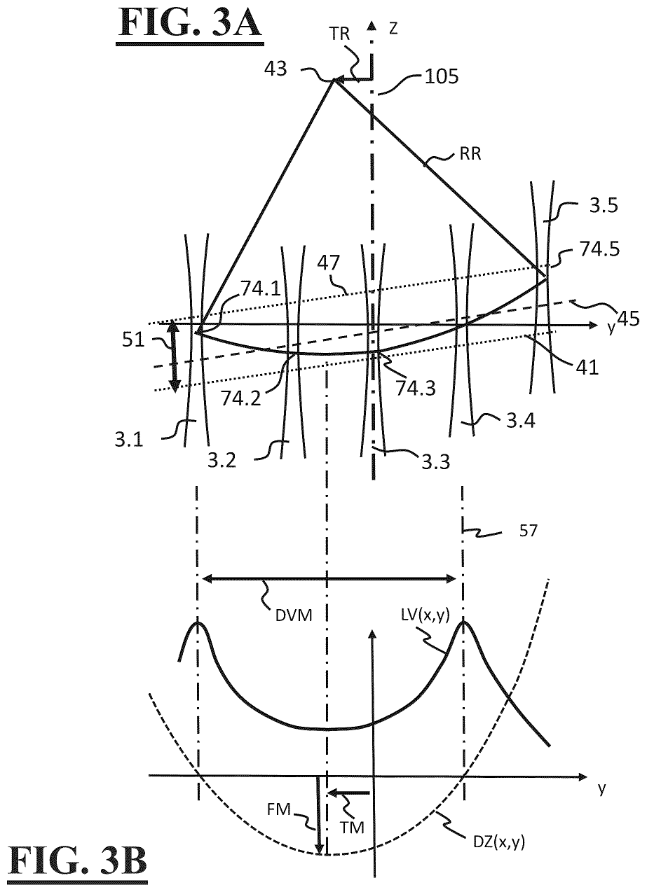

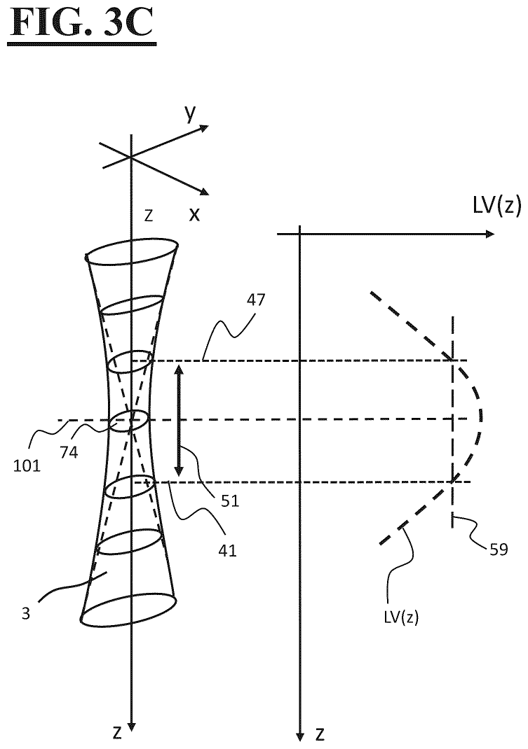

FIGS. 3A-3C illustrate an imaging operation with a plurality of primary charged particle beamlets. FIG. 3A shows the through-focus distributions of five primary electron beamlets 3.1 to 3.5 with a highly exaggerated field curvature. Due to the properties of a multi-beam system 1, the beam waists 74.1 to 74.5 of the primary beamlets 3.1 to 3.5 are formed on a curved image surface 101. The curvature radius RR and the image surface tile TR of the ideal image surface 101 depends on the imaging setting of the multi-beam system 1, for example the focus setting adjusted by objective lens 102, the selected numerical aperture, beamlet pitch, and the landing energy adjusted by sample potential supply 503. Typically, the wafer surface 25 (not shown) is arranged in region between upper surface 47 and lower surface 41 with ideal center surface 45. Thereby, each primary beamlet is focused on the wafer surface 25 with minimal distance and a blurring due to defocus is kept within acceptable ranges. According to the first embodiment, the operation control processor is configured to determine the resolution loss due to local defocus of each beamlet. An example is illustrated in FIG. 3b. A wafer surface 25 was placed perpendicular to the z-direction, such that beamlets 3.1 and 3.4 have minimum defocus and therefore minimum resolution loss due to defocus blur. Images acquired during an image acquisition are evaluated according to contrast measures such as intensity gradient or slope computation, spectral analysis, histogram analysis or local contrast computation by C=(Imax−Imin)/(Imax+Imin). The image contrast measure LV(x,y) is illustrated in FIG. 3B, which shows a cross-section through the contrast measure or contrast map LV(x,y) in y-direction, with two maximum contrast positions corresponding to the minimum defocus of the spherical focus plane deviation DZ(x,y) of the beam waists 74.1 to 74.5 to the y-plane.

The spherical focus plane deviation DZ(x,y) typically generates a resolution or contrast map over the plurality if primary beamlets of circular shape, with a contrast or resolution maximum of a ring shape. FIG. 3B shows a cross-section through the resolution or contrast map LV(x,y)). FIG. 3C illustrates the relation between local image contrast LV over defocus z from an ideal focus position or beam waist 74 at z=0. From a contrast threshold 59, a focus range 51 between a lower and upper defocus positions 41 and 47 can be derived. Typically, a local image contrast decreases linearly with larger defocus. The local image contrast over defocus LV(z) may further show an asymmetry due to residual spherical aberration, or a dependency on orientations of semiconductor patterns on a wafer surface due to astigmatism. Such a contrast curve LV(z) in dependency of image plane deviation from ideal focus position can be determined in a calibration of a multi-beam system 1.

During an inspection, an absolute contrast also depends on material composition, the pattern to be imaged, the topography, the noise level and charging effects at the surface of an object. Therefore, a derivation of defocus or image plane position from absolute contrast values is not possible; however, with a plurality of local contrast values LV(x,y) over a large image of a surface segments 251 (see FIGS. 2A and 2B) and with the model of a spherically curved and tilted image surface 101 of the multi-beam charged particle beam system 1, a defocus or focus offset can be determined with high accuracy. According to the first embodiment, the multi-beam charged particle beam system 1 is configured to measure during image acquisition the local visibility or contrast map LV(x,y) of the image of a surface segment 251 and to derive—with the predetermined contrast over focus LV(z)—the offset DZ(x,y) between object surface 25 and ideal image plane 101 from the contrast map LV(x,y). The multi-beam charged particle beam system 1 is configured to determine from the contrast map LV(x,y) the radius RM and the image plane tilt vector TM=[TMx, TMy] of the actual best focus surface (RM and TM for “measured” radius and “measured” tilt vector).

The field curvature radius R and the image plane tilt vector T is a function of the image setting, for example of the magnification, the numerical aperture, or the mean focus distance of the plurality of primary beamlets. For each image acquisition, an image setting is selected. The multi-beam charged particle beam system 1 is configured for a selection of different image settings including a lens power of the objective lens 102, a lens power of the at least one field lens 103, and a landing energy of primary charge particle beamlets 3.

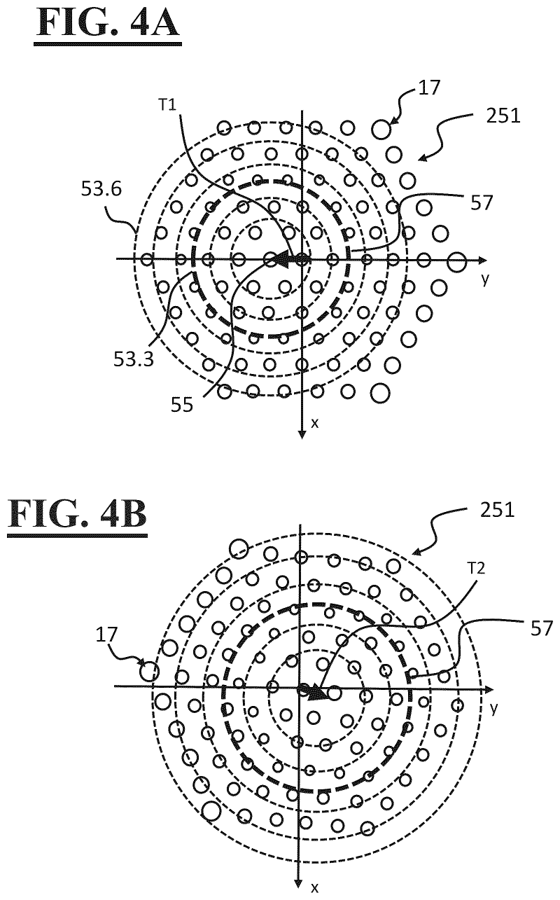

FIGS. 4A and 4B show two examples for two different image settings. Each individual beamlet 3 is illustrated by a circle 17 of different size corresponding to the resolution of the beamlet 3. The smaller the circle 17, the larger the local image contrast obtained by a beamlet 3. Circular lines of equal contrast 53 are centered around decentered centers of symmetry 55. FIG. 4A shows the effect of a first reference field curvature radius R1 and first reference image plane tilt vector T1 of a first imaging setting. FIG. 4B shows a second reference radius R2 and second reference image plane tilt vector T2 at a second imaging setting, leading to two different distributions of contrast over an image field 251 of a multi-beam charged particle beam system 1. As illustrated in FIG. 4B, each image setting typically also includes a different rotation angle of the plurality of primary charged particle beamlets on a wafer surface 25.

In some examples, a multi-beam charged particle beam system 1 is further configured for an exchange of a primary multi-beamlet-forming unit 305 for forming a first plurality of primary charged particle beamlets with a first primary multi-beamlet-forming unit and at least a second plurality of primary charged particle beamlets with a second primary multi-beamlet-forming unit. For each image setting, a reference field curvature radius RR and a reference image plane tilt vector TR can be determined in advance, for example during a calibration of a multi-beam charged particle beam system 1. The multi-beam charged particle beam system 1 comprises a memory configured for storing a plurality of reference field curvature radii RR and a reference image plane tilt vectors TR for a plurality of different image settings. The multi-beam charged particle beam system 1 is configured to determine a difference between a measured field curvature radius RM and a measured image plane tilt vector TM with the corresponding reference field curvature radius RR and reference image plane tilt vector TR according to the selected image setting. The multi-beam charged particle beam system 1 is configured to determine a focus correction signal from the difference and to provide the focus correction signal to compensation elements of the multi-beam charged particle beam system 1. Thereby, a wafer surface is kept in a best focus position with a minimum contrast loss during image acquisition. The control or correction signal is directly determined from images acquired during use, and no further time-consuming focus measurement methods are used. Thereby, a throughput is increased.

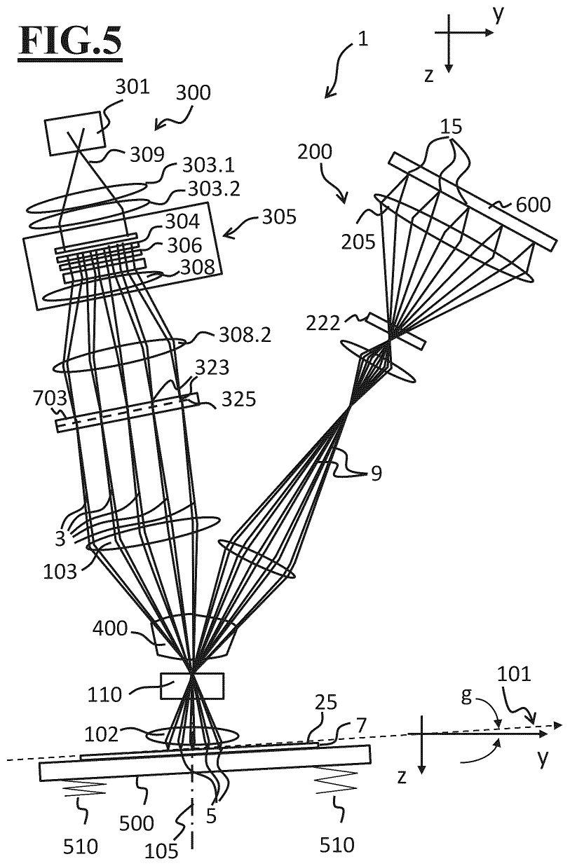

FIG. 5 illustrates an example of a wafer inspection with a planar wafer surface 25. The wafer surface 25 is adjusted with a tilt angle g corresponding to an image plane tilt vector T by tilt actuators 510 of the stage 500. Thereby, an image plane tilt component is compensated. The image plane tilt angle g is determined from the measured field curvature radius RM and measured image plane tilt vector TM with sin (g)=TM/RM; after adjusting the wafer stage in the tilted position with angle g, the measured image plane tilt vector TM ideally vanishes completely, i.e. TM=[0,0]. After determining the tilt position angle g of an actual acquired image, the multi-beam charged particle beam system 1 is configured to laterally move the wafer in the tilted plane 101 to a next inspection site for an acquisition of a next inspection image. A similar principle is applied in case of a wafer bending. More details are explained below.

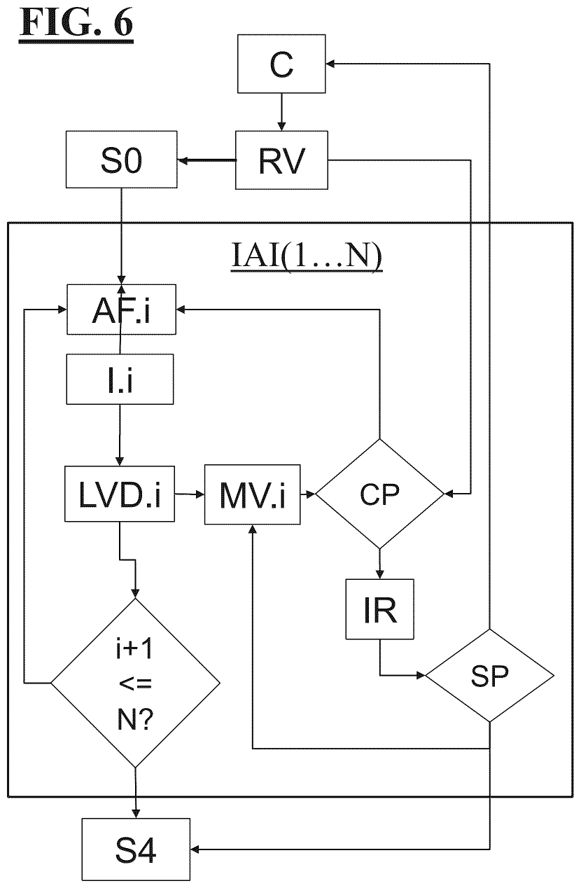

FIG. 6 shows a method of improved image acquisition according to a second embodiment of the disclosure.

In an optional step C, a multi-beam charged particle beam system 1 is calibrated. During the calibration step, reference values RV for field curvature RR, reference focus offset DFR and reference image plane tilt vector TR are determined for at least one image setting. Reference values RV are stored in a memory for the at least one image setting. Reference values RV can be determined with a reference object, such as a reference wafer or any other object, such as a patterned, planar wafer with semiconductor structures of sizes of the desired resolution of an imaging task between 3 nm and 10 nm. During a calibration, reference values RV do not need to be determined for many imaging setting. Typically, it is sufficient to determine reference values RV for a limited number of imaging settings.

In step S0, an inspection task is organized. A wafer 7 is loaded to the wafer stage 500 and a list of N inspection sites 6.1 . . . 6.N on the wafer surface 25 is received and configured. An imaging setting is selected for each of the inspection sites. For each imaging setting, a reference value RV of a reference focus offset FR, field curvature radius RR and image plane tilt TR is determined. The reference focus offset FR, reference field curvature radius RR and reference image plane tilt vector TR are typically given by differentiable functions depending on individual image settings such as lens excitations of landing energy of primary electrons. Therefore, in an example, reference values RV are determined during step S0 by interpolation, including using polynomial interpolation functions from predetermined reference values at preselected imaging settings, which have been used during a calibration of the multi-beam charged particle beam system 1 during step C.

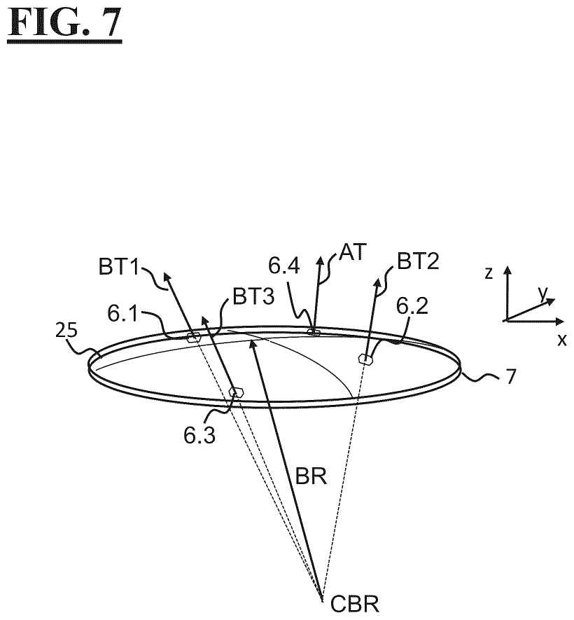

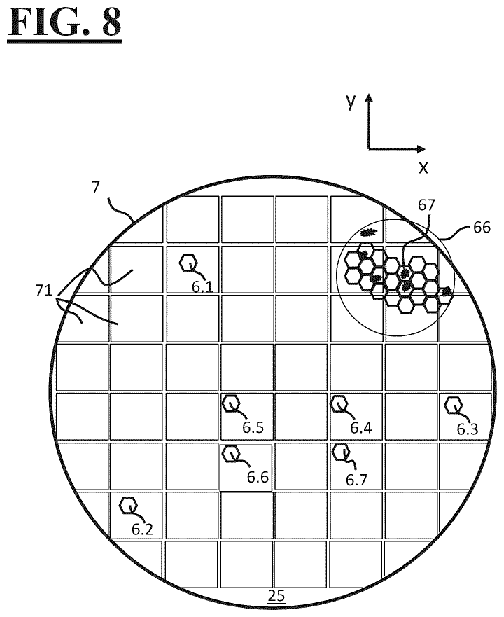

The number N of different inspections sites can be any number between N=2 and more, for example N=10, N=100, or N=1000 or more. At each inspection site, and image corresponding to the image field size (see image of surface segment 251 in FIGS. 2A and 2B) of the plurality of primary beamlets 3 is acquired. An image field size can for example be about 100 μm×100 μm or more. Examples of series of inspections sites 6.1, 6.2 and further are illustrated in FIGS. 7 and 8 and described below.

In an example, the inspection task comprises a repeated imaging at an identical position of the wafer surface, i.e. a subsequent inspection site is equal to a previous inspection site. For example, a series of images is obtained from a surface segment 251 with fast scanning times and large noise level of each individual image. Thereby, charging of a wafer surface 25 is reduced. With a larger time delay between two image acquisitions at the same inspection site, accumulated charge at a wafer surface 25 can decay, such that a subsequent image acquisition is not deteriorated by a charging of a previous image acquisition. The final image is obtained by averaging over the series of images, thereby a noise level is reduced.

In Loop IAI (1 . . . . N), each inspection site of the at least N=2 different inspection sites 6.i (with i=1 . . . . N) at different positions is subsequentially adjusted by the wafer stage within the image field of the multi-beam charged particle beam system 1 and at least a first image at the first inspection site 6.1 and a second image at the second inspection site 6.2 are acquired.

Each loop comprises the steps of:
Step AF.i for setting the ith imaging setting of the ith image acquisition and for adjusting the ith inspection site 6.i on the wafer surface 25 in or close to the image surface 101 of the ith imaging setting.
Step I.i of acquiring the ith inspection image at the ith inspection site 6.i.
Step LVD.i of determining the local image contrast map LV(x,y) of the ith image.
Step MV.i of determining the measured values MV.i of at least one of a focus offset FM.i, a field curvature radius RM.i and an image plane tilt vector TM.i from the local image contrast map LV(x,y) of the ith image.
Step CP of comparing measured values MV.i to the reference values RV.i as determined from the stored reference values RV for the ith image setting.
Control step for determining, whether the desired number N of inspection tasks is accomplished (by determining whether i+1<=N or whether the maximum number N of inspection sites has been achieved).

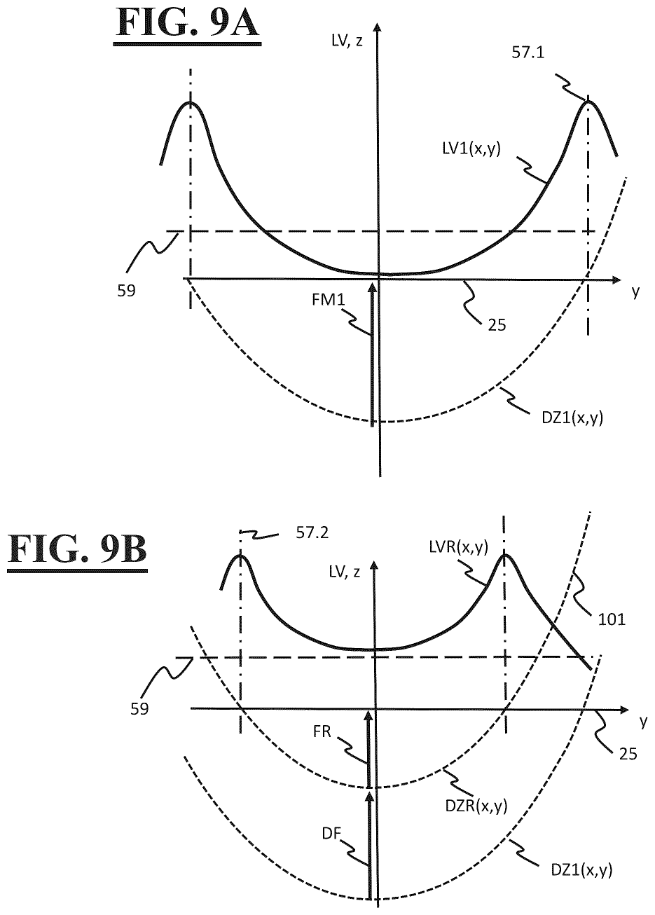

During each step LVD, a local image contrast map LV(x,y) of an image of surface segment 251, also called local visibility, is determined with fast routines selected from a group of routines including: an intensity gradient determination, a local histogram analysis of grey levels, a local visibility determination according to V=(Imax−Imin)/Imax+Imin), a local computation of a normalized image log slope (NILS), an analysis of a local frequency spectrum, an analysis of a convolution result with an edge filter. During each step MV.i, actual values of at least one of a defocus FM.i, a field curvature radius RM.i and an image plane tilt TM.i are determined. For the determination, in an example a contrast-over-defocus model with a model radius and model tilt is applied and measured values MV.i are determined by optimization. In an example, a predetermined contrast-over-defocus model is applied to the local visibility LV.i and focus offset FM, field curvature radius RM is determined by best fit approximation. For illustration, reference is made to FIGS. 3B, 3C, 9A and 9B. For larger focus offset or defocus DZ(x,y), as a good approximation, the local visibility LV drops linear with the absolute value of defocus DZ(x,y). It is further known that the field curvature radius RM is positive in the coordinate system of FIGS. 3A-3C with z-axis pointing upwards, opposite to the propagation direction of the primary charged particles. In other words, the center of field curvature is above the wafer surface 25. Therefore the ambiguity of the sign of the defocus curve DZ(x,z) is resolved by prior knowledge.

The beamlets 3 which have with smallest distance of the beam waists 74 to a wafer surface 25, where DZ(x,y)=0, generate the maximum possible image contrast. Due to the spherical field curvature, the maximum image contrast LV within the image field is achieved on a circular ring 57 within the image field (see FIGS. 4A and 4B, in which the circles of minimum spot diameters and maximum local image contrast are highlighted by bold lines 57). In an example, the focus offset FM is determined from the diameter DVM of the circle of maximum image contrast 57 and the field curvature radius RM. In an example, the image plane tilt vector TM is determined from the center of the circle of maximum image contrast 57.

The measured values MV.i are compared in step CP to reference values RV.i according to the imaging setting of the ith image acquisition. The deviation DV.i between measured values MV.i and reference values RV.i is determined with DF.i=FM.i−RF.i, DR.i=RM.i−RR.i and DT.i=TM.i−TR.i.

In an example, steps MV comprises a determination of a rotation angle of the plurality of primary charged particle beamlets 3 (see FIG. 4B). Typically, a change of a position of the image surface 101 with magneto-dynamic objective lens 102 may also induce a change of the rotation angle of the arrangement of the plurality of primary charged particle beamlets 3.

The differences or deviations DV.i are provided to step AF.(j) for the next or any subsequent image acquisition (with j>i). Thereby, for the next adjustment in step AF.(j), reference values RV.(j) can be adjusted and corrected by the deviations DF.i, DR.i and DM.i, which are determined in previous step MV.i of the previous image acquisition step I.i.

In an example, the deviations DF.i, DR.i and DT.i are further tracked in tracking step IR. During tracking step IR, the deviations DF, DR and DT are analyzed. In a first example, the adaptive focus and image plane tilt adjustment according to step AF converges and the deviations DF, DR and DT decrease during a series of image acquisitions. In a second example, the adaptive focus and image plane tilt adjustment according to step AF does not converge. A lack of converging can have at least two reasons:
A) The multi-beam charged particle beam system 1 involves a recalibration of the reference values RV. This may happen due to drift or degradation of the system performance of the multi-beam charged particle beam system 1.
B) The wafer surface 25 is not planar.

Typically, a wafers surface 25 is a planar surface, but a wafer 7 can be subject to a wafer bending or a wafer can be non-parallel or of wedged, i.e. the upper and lower wafer surfaces are not perfectly parallel. A resulting series of deviations DF, DR and DT due to a wafer bending and/or a wedged wafer are systematic. For example, a wedge angle W of a wafer can be determined from the constant component of a series of tilt angles DT. For example, a small wafer bending with bending radius BR can be determined from at least three tilt angles at three different inspection sites with different local surface tilts BT.1 to BT.3 according to the wafer bending radius BR. The local surface tilts BT.1 to BT.3 according to the wafer bending radius BR are illustrated in FIG. 7. FIG. 7 illustrates an example of a convex wafer bending with a convex wafer surface 25. Three inspection sites 6.1 to 6.3 are illustrated with three different surface normal vectors BT.1 to BT.3, from which the center of curvature CBR of the wafer bending is derived. The surface normal vectors BT.1 to BT.3 are determined from the difference vectors DT between the measured image plane tilt vectors TM and the expected reference tilt vectors TR. With the known bending radius BR, the local wafer tilt can be determined at any position on the surface 25 of wafer 7. An example is illustrated for the next, subsequent inspection site 6.4. At the x-y-coordinate of inspection site 6.4, the local surface normal vector AT to the wafer surface 25 is computed from the center of curvature CBR of the wafer bending and the wafer can be adjusted in step AF.4 according to the local surface normal vector AT at inspection site 6.4. For better illustration, the effect of wafer bending is highly exaggerated in FIG. 7. in presence of a wafer bending, the wafer 75 is moved with the method according the second embodiment by stage 500 not in a tilted plane as illustrated in FIG. 5, but merely on a virtual spherical surface according to the curvature of the wafer 7, such that the wafer surface 25 is kept close to the image surface 101.

In step SP, for example a series of at least tilt angles DT is monitored, and it is determined whether a systematic effect according to a wedged wafer or a wafer-bending is the most-likely source of a non-convergence of deviations DF, DR, and DT. A wafer wedge W and wafer bending radius BR can then be derived numerically and be considered during the determination of the measured values in subsequent step MV. Thereby, a local tilt of a wafer surface at each subsequent inspection site is determined and the wafer surface 25 is adjusted in the image surface 101 of the multi-beam charged particle beam system 1 with optimal focus offset FR during step AF at subsequent inspection sites, including a compensation of the local tilt of a wafer surface 25 at each subsequent inspection site. The compensation of the local tilt can for example be achieved by wafer stage actuators 510 (see FIG. 5), configured for adjusting a tilt angle of a wafer holding device or wafer chuck of the wafer stage 500.

In an example, if a series of difference values DF, DR and TM does not converge even after considering a wafer wedge angle W or wafer bending radius BR, a calibration of the multi-beam system 1 according to step C is initiated and at least one new set of reference values RV for at least one image setting is determined. The new reference values are stored in memory for use during a series of image acquisitions at a plurality of inspection sites according to an inspection task.

After acquisition of the last, Nth inspection image of a wafer inspection task on a wafer, the inspection images of the inspection sites, the deviations DF, DR and TR, the wafer wedge angle W and the wafer bending radius BR are stored in memory for later use. A later use can for example comprise a defect detection, a determination of a feature dimension, an analysis of a distribution of specific defects or feature dimensions on the wafer surface 25, or a repeated inspection of the same wafer with consideration of the determined wedge angle W or bending radius BR of the wafer, obtained during a previous inspection task.

The determination of local contrast LV, the determination of measured values MV and the comparison to reference values can be performed during and parallel to a series of image acquisition. The adjustments to an imaging setting determined from the comparison can be applied to a subsequent image acquisition at the same or a different inspection site. The method is not limited to be applied on direct sequences of pairs of two directly consecutive image acquisitions but can be applied to any sequences of image acquisitions within a series of image acquisitions. From any first image acquisition or sequence of image acquisitions, an adjustment of an imaging setting or wafer stage adjustment can be derived for any subsequent image acquisition or series of image acquisitions.

FIG. 8 shows a simplified example of a wafer inspection task at an example of a wafer 7 with a plurality of wafer dies 71 on the surface 25. In this example, the first three inspection sites 6.1 to 6.3 are located at positions of the periphery of the wafer 7. Thereby, a wafer bending radius BR, or wedge angle W of a wafer can be determined with high precision. Next, inspection sites 6.4 to 6.7 are selected to perform measurements at process control monitors (PCM), which are for example sensitive to an exposure or an etching process. Next, a cluster of inspection sites 66, comprising a plurality of adjacent image fields of the plurality of primary charged particle beamlets for imaging a larger area or at least one wafer die 71. Thereby, distributions of defects 67 or defect densities are determined. For each image acquisition, contrast information of a previously acquired image is utilized to adjust the wafer surface 25 with optimal focus offset RF to the image surface 101 of the multi-beam charged particle beam system 1. With a multi-beam charged particle beam system 1 according to the first embodiment and the method of operating a multi-beam system according to the second embodiment, large areas of a wafer surface 25 can be inspected in shorter time, and for example properties of semiconductor features such as fins, interconnections, HAR channels, transistor gates, doped areas, process control monitors, and the like, can be measured in shorter time. Furthermore, defects can be detected, for example defects arising from contamination during wafer processing, or mask defects. The result can trigger a fabrication process improvement, for example a mask repair operation, a cleaning operation, or an adjustment of fabrication process parameters of an individual fabrication process step during semiconductor wafer fabrication.

FIGS. 9A and 9B illustrates an example of the method according to the second embodiment. FIG. 9A shows a first measurement of a local image contrast LV1(x,y) at a first inspection site 6.1. The image circle of maximum contrast 57.1 is at a peripheral position due to a large focus offset FM1. From the local image contrast LV1(x,y), a first deviation DZ1(x,y) from the wafer-surface 25 of the plurality of primary beamlets is computed. The first deviation DZ1(x,y) shows a field curvature with radius R1 and a first, large defocus or focus offset FM1. The focus offset FM1 has an impact on the local imaging contrast LV1(x,y), and with the focus offset FM1 of the first image acquisition, a major part of the image is out of focus for a specific contrast or desired resolution, given by a contrast threshold 59.

FIG. 9B shows a result of the method according to the second embodiment. FIG. 9B shows an ideal local image contrast LVR(x,y) with a balanced focus offset FR of the wafer surface 25 with respect to the image surface 101, and the beamlets are in an ideal reference position DZR(x,y) and an image contrast LVR(x,y) is above a contrast threshold 59 for a maximum number of primary beamlets 3 (not shown).

In this example, the field curvature radius R1 and image plane tilt vector does not show any difference to the reference values, but measured local contrast curve LV1(x,y) differs from reference local contrast curve LVR(x,y) by the effect of the focus difference DF=FM1-FR. An example with a image plane tilt vector is illustrated in FIGS. 3A and 3B. An image plane tilt vector TM is determined from a displacement of a center of symmetry of the local contrast curve LV(x,y). In an example, a field curvature radius RM is determined from for example a curvature of the local image contrast map LV(x,y) or a difference between a maximum and minimum contrast value of the local image contrast map LV(x,y). For example, with a large field curvature radius, a focus distance across an image field is smaller and a contrast difference between a minimum local contrast and a maximum local contrast of the local image contrast map LV(x,y) is smaller.

According to the method of the second embodiment, the focus offset FM1 is determined during step MV.1 from the local image contrast LV1(x,y). The focus offset FM1 is computed for example by applying a contrast-over-defocus model to LV1(x,y) or from the diameter of the image circle of maximum image contrast 57.1. Based on the predetermined knowledge of field curvature radius R1, which is eventually verified during step MV by computing RM. 1, the focus offset FM1 during the first measurement is determined from a single image of a surface 25 of a structured semiconductor wafer 7. In step CP, the focus offset FM1 is compared to the reference focus offset FR according to the imaging setting used at the first inspection site 6.1. The difference DF is determined and used for an adjustment of the second imaging setting for the second measurement at the second inspection site during step AF.2.

According to a further example, the method of the second embodiment is further suitable for a tracking of a drift or degradation of a multi-beam charged particle beam system. Thereby, for example a frame averaging, or a multi-modal image acquisition can be performed.

According to a first example of frame averaging, a series of images is acquired at a first inspection site (6.1) with short dwell times; thereby, a charging of charging objects is minimized. Each single image, however, shows an increased noise level. To compensate the increased noise level, an average image is computed from the series of images, comprising at least two, three, five or more images. However, during the acquisition of the several images, drifts may occur with change the position of the inspection site 6.1 as well as position of the surface 25 of the wafer 7. Furthermore, charges may slowly accumulate at the surface of the wafer, and—induced by the charging—an image surface 101 is affected. Induced by the charging, an axial position or focus offset of the plurality of primary charged particle beamlets 3 and shape of the image surface 101 changes during the series of images. By the steps of determining the focus offset during or after each image acquisition, a focus offset can be compensated continuously during the acquisition of a series of images. Focus offsets reduce the image contrast, and it is therefore not possible to compensate focus offset by digital post-processing of for example laterally displaced images. With frame averaging and with “on the fly” focus correction according to the method of the second embodiment, high resolution images can be obtained.

The adjustment of the image setting is however not limited to a correction of the focus offset FM or image plane tilt TM. In the second example of multi-modal imaging, a series of images is obtained with for example different contrast modes for the imaging of secondary electrons or different kinetic energies of primary beamlets. Since the secondary electron yield is depending on the kinetic energy of primary electrons, different charging properties of a semiconductor sample are achieved with a first and a second image setting with first and second kinetic energies of primary electrons. According to the second embodiment, a series of images acquired with different kinetic landing energies of primary electrons and a drift in focus offset FM or image plane tilt TM is determined and compensated during acquisition of the series of images. A focus offset FM.1 or image plane tilt TM.1 is determined from a first measurement with a first image setting and transferred to a second measurement with a second image setting. Other examples of multi-modal imaging are series of images with different apertures filters 284.a, 284.b in the secondary electron beam path. Thereby, different charging contrasts or topography contrasts can be measured and an image fusion of the different images of a series of at least two images can provide images of a wafer surface with higher precision.

A method according to the second embodiment for wafer inspection with a multi-beam charged particle beam system is therefore comprising the steps of acquiring a first image at a first inspection site (6.1) on a wafer surface (25) with a first imaging setting of the plurality of primary charged particle beamlets (3), and acquiring at least a second image at a second inspection site (6.2) on the wafer surface (25) with a second imaging setting of the plurality of primary charged particle beamlets (3). In an example, the second inspection site (6.2) is identical to the first inspection site (6.1) and a series of at least two repeated image acquisitions at the first inspection site (6.1) is performed, wherein between each image acquisition, a measurement value MV.i consisting of at least one of a focus offset FM.i, a field curvature radius RM.i and an image plane tilt vector TM.i is determined. From the measurement value MV.i, at least one deviation value DV.i is determined and an adjustment of a subsequent imaging setting of the plurality of primary charged particle beamlets (3) is performed according to the at least one deviation value DV.i. The second image acquisition at the first inspection site (6.1) can be obtained as a repeated image with a second image setting similar to the first image setting, where only the image plane or image plane tilt is adjusted. The second image acquisition at the first inspection site (6.1) can be obtained as a repeated image with a second image setting different to the first image setting, wherein the second image setting differs from the first image setting by at least one of an image setting property consisting of a kinetic landing energy of the primary electron, a scanning direction or scanning pattern, an aperture filter 284, an aperture filter placement.

In an example, the focus offset correction during a series of image acquisitions for frame averaging or multi-modal imaging can be combined with a correction of lateral drift during postprocessing of the acquired images.

With the method, a fast focus-following function is enabled in a multi-beam charged particle beam system with a plurality of primary charged particle beamlets during the performance of an inspection task without the desire of special focus adjustment methods or algorithms using series images at several focus planes and reference test objects. The method relies on predetermined knowledge or information about field curvature radius and image plane tilt vector of specified image settings. From the predetermined information, a model-based or analytic derivation of a deviation from an ideal image plane and a wafer surface position can be determined from inspection images and deviations can be adjusted for subsequent image acquisitions. The method is further configured to determine and consider a wedged wafer or a wafer bending.

The disclosure encompasses following clauses:

Clause 1: A method of wafer inspection with a multi-beam charged particle beam system (1), comprising:
determining at least a first inspection site (6.1) and a second inspection site (6.2) on a wafer surface (25);
-acquiring a first image at the first inspection site (6.1) on a wafer surface (25) with a first imaging setting of the plurality of primary charged particle beamlets (3);
determining a first local image contrast map LV(x,y) of the first image;
determining a measurement value MV.1 from the first local image contrast map LV(x,y), wherein the measurement value MV.1 comprises at least one of a first focus offset FM.1, a first field curvature radius RM.1 and a first image plane tilt vector TM.1;
-determining a reference value RV.1 according to the first imaging setting from a memory, wherein the reference value RV.1 comprises at least one of a reference focus offset RF.1, a reference field curvature radius RR.1 and a reference image plane tilt vector TR.1;
determining at least one deviation value DV.1 between the measurement value MV.1 and the reference value RV.1;
determining from the at least one deviation value DV.1 at least one of an adjustment of the second inspection site (6.2) and an adjustment of a second imaging setting of the plurality of primary charged particle beamlets (3);
acquiring a second image at the second inspection site (6.2) on the wafer surface (25) with the second imaging setting of the plurality of primary charged particle beamlets (3).

Clause 2: The method according to clause 1, comprising
computing a difference DT.1 between the first image plane tilt vector TM.1 and the reference image plane tilt vector TR.1;
determining, from the difference DT.1, a tilt angle adjustment of the wafer surface (25) with a wafer stage (500) at the second inspection site (6.2).

Clause 3: The method according to clause 1 or 2, comprising
computing a difference DF.1 between the measured focus offset FM.1 and the reference focus offset FR.1;
determining, from the difference DF.1, at least one of an axial movement of the wafer stage (500) and an adjustment of a focus offset of the multi-beam charged particle beam system (1) at the second inspection site (6.2).

Clause 4: The method according to any of the clauses 1 to 3, comprising
computing a difference DR.1 between the measured field curvature radius RM.1 and the reference field curvature radius RR.1;
determining, from the difference DR.1, an adjustment of a field curvature of the multi-beam charged particle beam system (1) at the second inspection site (6.2).

Clause 5: The method according to any of the clauses 1 to 4, further comprising
determining a second local image contrast map LV(x,y) of the second image;
determining a second measurement value MV.2 from the second local image contrast map LV(x,y), wherein the second measurement value MV.2 comprises at least one of a second focus offset FM.2, a second field curvature radius RM.2 and a second image plane tilt vector TM.2;
determining a second reference value RV.2 according to the second imaging setting from a memory, wherein the second reference value RV.2 comprises at least one of a reference focus offset RF.2, a reference field curvature radius RR.2 and a reference image plane tilt vector RT.2;
determining at least one second deviation value DV.2 between the second measurement value MV.2 and the second reference value RV.2;
determining from the at least one second deviation value DV.2 at least one of an adjustment of a third inspection site (6.3) and an adjustment of a third imaging setting of the plurality of primary charged particle beamlets (3);
acquiring a third image at the third inspection site (6.3) on the wafer surface (25) with the third imaging setting of the plurality of primary charged particle beamlets (3).

Clause 6: The method according to clause 5, further comprising iterating the steps of determining a local image contrast map LV(x,y), determining an ith measurement value MV.i, determining an ith reference value RV.i, determining at least one ith deviation value DV.i, determining from the at least one ith deviation value DV.i at least one of an adjustment of a subsequent jth inspection site (6.j) with j>i, and an adjustment of an jth imaging setting of the plurality of primary charged particle beamlets (3); and acquiring a jth image at the jth inspection site (6.j).

Clause 7: The method according to clause 6, comprising
determining, from at least three difference vectors DT.1 to DT.3 a wafer bending radius BR of a surface of a wafer (7),
considering the wafer bending radius BR during determining the adjustment of a subsequent inspection site (6.j).

Clause 8: The method according to clauses 6 or 7, comprising
determining, from at least three difference vectors DT.1 to DT.3 a wedge angle W of a wafer (7);
considering the wafer wedge angle W during determining the adjustment of a subsequent inspection site (6.j).

Clause 9: The method according to any of the clauses 6 to 8, comprising
tracking a series of at least three difference values DV.1 to DV.3;
analyzing whether the series of difference values DV.1 to DV.3 converges; and
triggering a calibration of the multi-beam charged particle beam system, when the series of difference values DV.1 to DV.3 is not converging.

Clause 10: The method according to any of the clauses 1 to 9, comprising
determining, in the local contrast map LV(x,y), a circle (57) of maximum image contrast;
determining, a diameter DVM of the circle (57) of maximum image contrast;
determining a focus offset FM from the diameter DVM of the circle (57).

Clause 11: The method according to clause 10, comprising
determining a center position of the circle (57) of maximum image contrast;
determining a image plane tilt vector TM from the center position of the circle (57).

Clause 12: The method according to any of the clauses 1 to 11, further comprising a repeated image acquisition at an inspection site.

Clause 13: The method according to any of the clauses 1 to 12, wherein the second image acquisition is subsequently following the first image acquisition.

Clause 14: A multi-beam charged particle beam system, comprising a control processor (800) including a memory (880) for storing executable software instructions, the control processor (800) being configured for executing the software instructions to perform any of the methods according to clauses 1 to 13.

Clause 15: A method of acquiring a series of images at an inspection site (6.1), comprising:
acquiring a first image at the inspection site (6.1) on a wafer surface (25) with a first imaging setting of the plurality of primary charged particle beamlets (3);
determining a first local image contrast map LV(x,y) of the first image;
determining a measurement value MV.1 from the first local image contrast map LV(x,y), wherein the measurement value MV.1 comprises at least one of a first focus offset FM.1, a first field curvature radius RM.1 and a first image plane tilt vector TM.1;
determining a reference value RV.1 according to the imaging setting from a memory, wherein the reference value RV.1 comprises at least one of a reference focus offset RF.1, a reference field curvature radius RR.1 and a reference image plane tilt vector TR.1;
determining at least one deviation value DV.1 between the measurement value MV.1 and the reference value RV.1;
determining from the at least one deviation value DV.1 at least one of an adjustment of the inspection site (6.1) and an adjustment of the imaging setting of the plurality of primary charged particle beamlets (3);
acquiring a second image at the inspection site (6.1) on the wafer surface (25) with the adjusted imaging setting of the plurality of primary charged particle beamlets (3).

Clause 16: The method according to clause 15, wherein the adjustment of the imaging setting comprises at least one of an adjustment of a focus offset FM of the image surface (101) and an adjustment of an axial position of the surface (25) of the wafer (7).

Clause 17: The method according to clause 15 or 16, further comprising image processing of the series of images.

Clause 18: The method according to clause 17, wherein the image processing comprises averaging of the series of images and an adjustment of lateral image displacements.

Clause 19: A method of determination of a focus plane deviation in a multi-beam charged particle beam system (1) from a single image acquisition, comprising:
acquiring an image at a first inspection site (6.1) on a wafer surface (25) with a first imaging setting of a plurality of primary charged particle beamlets (3);
determining a local image contrast map LV(x,y) of the image;
determining from the local image contrast map LV(x,y) at least one of a focus offset FM, a field curvature radius RM and an image plane tilt vector TM.

Clause 20: The method according to clause 19, further comprising determining an image circle of maximum contrast (57), and determining a focus offset FM from the circle of maximum contrast (57).

Clause 21: The method according to clause 19 or 20, further comprising determining the image plane tilt vector TM from a displacement of a center of symmetry of the local image contrast map LV(x,y).

Clause 22: The method according to any of the clause 19 to 21, further comprising determining the field curvature radius RM from a curvature of the local image contrast map LV(x,y) or a difference between a maximum and a minimum contrast value of the local image contrast map LV(x,y).

Clause 23: The method according to any of the clause 19 to 22, further comprising receiving at least one of a reference focus offset RF, a reference field curvature radius RR and a reference image plane tilt vector TR; and
determining at least one deviation value DV between at least one of a focus offset FM, a field curvature radius RM and an image plane tilt vector TM from a reference focus offset RF, a reference field curvature radius RR or a reference image plane tilt vector TR.

Clause 24: The method according to any of the clause 19 to 23, further comprising determining from the at least one deviation value DV at least one of an adjustment of a second inspection site (6.2) and adjusting of a second imaging setting of the plurality of primary charged particle beamlets (3).

Clause 25: The method according to clause 24, wherein the second inspection site (6.2) is identical to the first inspection site (6.1).

A list of reference numbers is provided:
1 multi-beamlet charged-particle system
3 primary charged particle beamlets, or plurality of primary charged particle beamlets
5 primary charged particle beam spot
6 inspection site
7 object or wafer
9 secondary electron beamlet, forming the plurality of secondary electron beamlets
11 secondary electron beam path
13 primary beam path
15 secondary charged particle image spot
17 circles illustrating image contrast of a beamlet
21 common pupil plane
25 surface of object
41 lower focal plane limit
43 center of field curvature
45 ideal focal plane for planar object
47 upper focal plane limit
51 depth of focus
53 circles of equal resolution or equal contrast, respectively
55 center of circles of equal resolution
57 circle of maximum image contrast or visibility
59 minimum resolution or visibility threshold
66 cluster of inspection sites
67 defect
71 die
74 beam waists of primary beamlets 3
100 object irradiation unit
101 image surface
102 objective lens
103 field lens
105 optical axis
108 first beam cross over
110 scanning deflector
112 electrostatic lens
200 detection unit
205 lens element
211 intermediate image plane
214 aperture filter module
215 movement mechanism
222 second deflection system
245 image patch of single beamlet
251 image of surface segment
284 aperture filter
300 charged-particle multi-beamlet generator
301 charged particle source
303 collimating lenses
304 filter plate
305 primary multi-beamlet-forming unit
306 multi-aperture plates
307 terminating multi-aperture plate
308 field lenses
309 primary electron beam
321 intermediate image surface
400 beam splitter unit
500 sample stage
503 Sample voltage supply
510 tilt actuators
600 image sensor
800 control unit
810 imaging control module
820 secondary beam-path control module
830 primary beam-path control module
840 Control operation processor
850 stage control module
860 scanning operation control module
880 memory
890 image processing engine
2105 optical axis of detection unit

What is claimed is:

1. A method of inspecting a wafer with a multi-beam charged particle beam system, a surface of the wafer comprising a first inspection site and a second inspection site different from the first inspection site, the method comprising:
acquiring a first image at the first inspection site with a first imaging setting of a plurality of primary charged particle beamlets generated by the multi-beam charged particle system;
determining a first local image contrast map of the first image;
determining a first measurement value from the first local image contrast map, the first measurement value comprising at least one member selected from the group consisting of a first focus offset, a first field curvature radius, and a first image plane tilt vector;
determining a first reference value according to the first imaging setting from a memory, the first reference value comprising at least one member selected from the group consisting of a first reference focus offset, a first reference field curvature radius, and a first reference image plane tilt vector;
determining a first deviation value between the first measurement value and the first reference value;
determining, from the first deviation value, at least one member selected from the group consisting of an adjustment of the second inspection site and an adjustment of a second imaging setting of a plurality of primary charged particle beamlets generated by the multi-beam charged particle system; and
acquiring a second image at the second inspection site with the second imaging setting of a plurality of primary charged particle beamlets generated by the multi-beam charged particle system.

2. The method of claim 1, comprising:
determining a difference between the first image plane tilt vector and the first reference image plane tilt vector; and
determining, from the difference, a tilt angle adjustment of the surface of the wafer at the second inspection site.

3. The method of claim 1, comprising:
determining a difference between the first measured focus offset and the first reference focus offset; and
determining, from the difference, at least one member selected from the group consisting of an axial movement of the wafer and an adjustment of a focus offset of the multi-beam charged particle beam system at the second inspection site.

4. The method of claim 1, comprising:
determining a difference between the first measured field curvature radius and the first reference field curvature radius; and
determining, from the difference, an adjustment of a field curvature of the multi-beam charged particle beam system at the second inspection site.

5. The method of claim 1, comprising:
determining a second local image contrast map of the second image;
determining a second measurement value from the second local image contrast map, the second measurement value comprising at least one member selected from the group consisting of a second focus offset, a second field curvature radius, and a second image plane tilt vector;
determining a second reference value according to the second imaging setting from a memory, the second reference value comprising at least one member selected from the group consisting of a second reference focus offset, a second reference field curvature radius, and a second reference image plane tilt vector;
determining a second deviation value between the second measurement value and the second reference value;
determining, from the second deviation value, at least one member selected from the group consisting of an adjustment of a third inspection site of the surface of the wafer and an adjustment of a third imaging setting of a plurality of primary charged particle beamlets generated by the multi-beam charged particle system; and
acquiring a third image at the third inspection site with the third imaging setting of the plurality of primary charged particle beamlets.

6. The method of claim 5, comprising repeating the method for each of a plurality of additional inspection sites on the wafer.

7. The method of claim 6, comprising:
determining, from at least three difference vectors, a wafer bending radius of the surface of the wafer; and
considering the wafer bending radius when determining an adjustment of a subsequent inspection site.

8. The method of claim 6, comprising:
determining, from at least three difference vectors, a wedge angle of a wafer; and
considering the wafer wedge angle when determining an adjustment of a subsequent inspection site.

9. The method of claim 6, comprising:
tracking a series of at least three difference values;
determining whether the series of difference values converges; and
triggering a calibration of the multi-beam charged particle beam system when the series of difference values does not converge.

10. The method of claim 1, comprising:
determining, in the first local image contrast map, a circle of maximum image contrast;
determining, a diameter of the circle of maximum image contrast;
determining a focus offset from the diameter of the circle of maximum image contrast.

11. The method of claim 10, comprising:
determining a center position of the circle of maximum image contrast; and
determining the first image plane tilt vector from the center position of the circle of maximum contrast.

12. The method of claim 1, comprising repeating image acquisition at an inspection site on the surface of the wafer.

13. The method of claim 1, wherein the second image acquisition follows the first image acquisition.

14. The method of claim 1, comprising determining the first and second inspection sites.

15. One or more machine-readable hardware storage devices comprising instructions that are executable by one or more processing devices to perform operations comprising the method according to claim 1.

16. A system, comprising:
one or more processing devices; and
one or more machine-readable hardware storage devices comprising instructions that are executable by the one or more processing devices to perform operations comprising the method according to claim 1.

17. A method of acquiring a series of images at an inspection site on a surface of a wafer, the method comprising:
acquiring a first image at the inspection site with a first imaging setting of a plurality of primary charged particle beamlets;
determining a first local image contrast map of the first image;
determining a measurement value from the first local image contrast map, the measurement value comprising at least one member selected from the group consisting of a first focus offset, a first field curvature radius, and a first image plane tilt vector;
determining a reference value according to the imaging setting from a memory, the reference value comprising at least one member selected from the group consisting of a reference focus offset, a reference field curvature radius, and a reference image plane tilt vector;
determining a deviation value between the measurement value and the reference value;
determining, from the deviation value, at least one member selected from the group consisting of an adjustment of the inspection site and an adjustment of the imaging setting of the plurality of primary charged particle beamlets; and
acquiring a second image at the inspection site with the adjusted imaging setting of the plurality of primary charged particle beamlets.

18. The method of claim 17, wherein adjusting the imaging setting comprises at least one member selected from the group consisting of adjusting a focus offset of the image surface and adjusting an axial position of the surface of the wafer.

19. The method of claim 17, further comprising processing the series of images.

20. The method of claim 19, wherein processing the series of images comprises averaging of the first and second images and adjusting lateral image displacements.

21. One or more machine-readable hardware storage devices comprising instructions that are executable by one or more processing devices to perform operations comprising the method according to claim 17.

22. A system, comprising:
one or more processing devices; and
one or more machine-readable hardware storage devices comprising instructions that are executable by the one or more processing devices to perform operations comprising the method according to claim 17.
